(19) United States
(12) Patent Application Publication
(10) Pub. No.: US 2025/0113531 A1
(43) Pub. Date: Apr. 3, 2025

(54) POWER SILICON CARBIDE BASED SEMICONDUCTOR DEVICES WITH SELECTIVE JFET IMPLANTS THAT ARE SELF-ALIGNED WITH THE WELL REGIONS AND METHODS OF MAKING SUCH DEVICES

(71) Applicant: Wolfspeed, Inc., Durham, NC (US)

(72) Inventors: Rahul R. Potera, Apex, NC (US); Joohyung Kim, Cary, NC (US); Shadi Sabri, Apex, NC (US)

(21) Appl. No.: 18/476,452

(22) Filed: Sep. 28, 2023

(51) Int. Cl. H01L 29/78; H01L 29/06; H01L 29/16

(52) U.S. Cl. CPC H10D 30/66; H10D 62/124; H10D 62/8325

(57) ABSTRACT

A semiconductor device such as a MOSFET or IGBT comprises a semiconductor layer structure that includes a drift layer having a first conductivity type, a JFET region that has the first conductivity type in the upper portion of the drift layer, a plurality of well regions having a second conductivity type in an upper portion of the drift layer, each well region forming a respective island within the JFET region when viewed in plan view, and a plurality of source regions having the first conductivity type, where each source region is within a respective one of the well regions. The JFET region comprises a plurality of spaced-apart first JFET sub-regions that each has a first doping concentration and a second JFET sub-region that has a second doping concentration that is lower than the first doping concentration, the second JFET region extending around at least one of the first JFET sub-regions when viewed in plan view.

### FIELD

The present invention relates to semiconductor devices and, more particularly, to power semiconductor devices and to methods of fabricating such devices.

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region that is electrically connected to the source terminal and a drain region that is electrically connected to the drain terminal are formed in the semiconductor layer structure that are separated by a channel region. A gate electrode that is electrically connected to the gate terminal is disposed adjacent the channel region and separated from the channel region by a thin oxide layer. A MOSFET may be turned on or off by setting a gate bias voltage that is applied to the gate electrode (through the gate terminal) to be above or below a threshold value. When the gate bias voltage exceeds the threshold value, the MOSFET is turned on (i.e., it is in its “on-state”), and current is conducted through the channel region between the source and drain regions. When the gate bias voltage is reduced below the threshold level, the MOSFET turns off and current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

As noted above, the gate electrode of a MOSFET is separated from the channel region by a thin oxide layer that is called a gate oxide layer. Other non-oxide gate dielectric layers may be used in certain applications in place of the gate oxide layer. It will be appreciated that the techniques according to embodiments of the present invention that are described herein are equally applicable to devices having gate dielectric layers formed with materials other than oxides.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT. The base current of the BJT is supplied through the channel of the MOSFET, thereby allowing a simplified external drive circuit (since the drive circuit only charges and discharges the gate electrode of the MOSFET).

In some applications, MOSFETs may need to carry large currents and/or be capable of blocking high voltages. Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate terminals may be on the top surface of the semiconductor layer structure and the drain terminal may be on the bottom surface of the semiconductor layer structure). The semiconductor layer structure may or may not include an underlying substrate such as a growth substrate.

The semiconductor layer structure of a power semiconductor device typically includes an “active region” in which one or more functional semiconductor devices are formed. The active region acts as a main junction for blocking voltage during reverse bias (off-state) operation and providing current flow during forward bias (on-state) operation. The power semiconductor device may also have an edge termination structure such as, for example, guard rings or a junction termination extension, in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the resultant structure may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

One failure mechanism for a power MOSFET is the so-called “breakdown” of the gate oxide layer. The gate oxide layer is subjected to high electric fields during normal device operation. The stress on the gate oxide layer caused by these electric fields generates defects in the oxide material, and these defects build up over time. When the concentration of defects reaches a critical value, a so-called “percolation path” may be created through the gate oxide layer that electrically connects the gate electrode to the source or drain region, thereby creating a short-circuit that can destroy the device. The “lifetime” of a gate oxide layer (i.e., how long the device can be operated before breakdown occurs) is a function of, among other things, the magnitude of the electric field that the gate oxide layer is subjected to and the length of time for which the electric field is applied. FIG. 1 is a schematic graph illustrating the relationship between the operating time until breakdown occurs (the “gate oxide lifetime”) and the level of the electric field applied to the gate oxide layer. This graph assumes that the same electric field is always applied (which is not necessarily the case). As shown in FIG. 1, the relationship may, in some cases, be generally linear when the gate oxide lifetime is plotted on a logarithmic scale. The important point to take from FIG. 1 is that as the electric field level is increased, the lifetime of the gate oxide layer decreases exponentially. The lifetime of the gate oxide layer may be increased by increasing the thickness of the gate oxide layer, but various performance parameters of a MOSFET may be a function of the thickness of the gate oxide layer and thus increasing the thickness of the gate oxide layer is typically not an acceptable way of increasing the lifetime of the gate oxide layer.

FIG. 2 is a schematic cross-sectional view of a small portion of a conventional silicon carbide power MOSFET 1. The cross-section of FIG. 2 shows one full unit cell of the MOSFET 1 and portions of two adjacent unit cells. As shown in FIG. 2, the MOSFET 1 includes a heavily-doped n-type (n+) silicon carbide semiconductor substrate 10. A lightly-doped n-type (n⁻) silicon carbide drift region 20 is provided on the upper surface of the substrate 10. Moderately-doped (p) p-type wells 30 (also referred to as “p-wells”) are formed on or in upper portions of the n-type silicon carbide drift region 20. Each p-well 30 includes a main p-well 32 and a pair of side p-wells 34. The main p-wells 32 have a doping concentration of, for example, between 5×10¹⁸/cm⁻³ and 5×10¹⁹/cm⁻³. The dopant concentration is generally higher the deeper the p-well 32 extends into the silicon carbide drift region 20. The side p-wells 34, which serve as the channels regions, are more lightly doped with p-type dopants than the main p-wells 32. Heavily-doped (n+) n-type silicon carbide source regions 40 are formed in upper portions of the p-wells 30. The portions of the drift region 20 that are between adjacent p-wells 30 are referred to as JFET regions 22. The JFET regions 22 may be more heavily doped than the remainder of the drift region 20 in some cases. Each JFET region 22 may have the same width in the direction between the adjacent p-wells 30 that define the JFET regions 22, and this width is referred to herein as the “JFET gap.” The n-type silicon carbide substrate 10, n-type silicon carbide drift region 20, the JFET regions 22, the p-wells 30 and the n-type source regions 40 formed therein may together comprise a semiconductor layer structure 50 of the MOSFET 1.

A patterned silicon oxide gate insulating layer 60 is formed on the upper surface of the semiconductor layer structure 50. A gate electrode layer 70 that includes a plurality of gate electrodes 72 is formed on the gate insulating layer 60 opposite the semiconductor layer structure 50. An intermetal dielectric pattern 80 covers the gate electrodes 72. The intermetal dielectric pattern 80 includes a plurality of openings 82 that expose the upper surface of the semiconductor layer structure 50. A source metallization layer 90 is formed on the intermetal dielectric pattern 80 and within the openings 82 in the intermetal dielectric pattern 80 so as to contact the heavily-doped n-type source regions 40 and portions of the main wells 32 that extend to the upper surface of the semiconductor layer structure 50. A drain contact 92 is formed on the lower surface of the substrate 10.

As noted above, channel regions are provided in the side p-wells 34. The channel regions electrically connect the n-type source regions 40 to the JFET regions 22 when a sufficient gate bias voltage is applied to the gate electrode 70. When such a gate bias voltage is applied to the gate electrode 72 (through the gate terminal of the MOSFET), current may flow from the source contact 90 (which serves as or is electrically connected to the source terminal of the MOSFET) to the n-type source regions 40 through the channel regions 34 to the JFET regions 22. The current flows from the JFET regions 22 through the drift region 20 and the substrate 10 to the drain contact 92, which serves as or is electrically connected to the drain terminal of the MOSFET.

### SUMMARY

Pursuant to some embodiments of the present invention, power semiconductor devices are provided that comprise a semiconductor layer structure that includes a drift layer having a first conductivity type, a JFET region that has the first conductivity type in the upper portion of the drift layer, a plurality of well regions having a second conductivity type in an upper portion of the drift layer, each well region forming a respective island within the JFET region when viewed in plan view, and a plurality of source regions having the first conductivity type, where each source region is within a respective one of the well regions. The JFET region comprises a plurality of spaced-apart first JFET sub-regions that each has a first doping concentration and a second JFET sub-region that has a second doping concentration that is lower than the first doping concentration, the second JFET region extending around at least one of the first JFET sub-regions when viewed in plan view. Additionally or alternatively, the second JFET region may extend around at least one of the well regions when viewed in plan view.

In some embodiments, the first JFET sub-regions comprise implanted regions and the second JFET sub-region comprises an un-implanted region.

In some embodiments, the plurality of well regions are arranged in columns, where the well regions in adjacent columns are offset from each other in a column direction. In some embodiments, each well region has a hexagonal shape when viewed in plan view.

In some embodiments, each first JFET sub-region has an annular hexagonal shape when viewed in plan view.

In some embodiments, each first JFET sub-region surrounds a respective one of the well regions when viewed in plan view.

In some embodiments, each first JFET sub-region is positioned between a respective one of the well regions and the second JFET sub-region when the semiconductor device is viewed in plan view.

In some embodiments, the second JFET sub-region comprises a continuous region that surrounds each of the first JFET sub-regions when viewed in plan view.

Pursuant to further embodiments of the present invention, power semiconductor devices are provided that comprise a semiconductor layer structure that includes a drift layer having a first conductivity type, a JFET region that has the first conductivity type in the upper portion of the drift layer, a plurality of well regions having a second conductivity type in an upper portion of the drift layer, each well region forming a respective island within the JFET region when viewed in plan view, and a plurality of source regions having the first conductivity type, where each source region is within a respective one of the well regions. The JFET region comprises a continuous first JFET sub-region that extends around the plurality of well regions and that has a first doping concentration and a plurality of spaced-apart second JFET sub-regions that each has a second doping concentration, where the second doping concentration is lower than the first doping concentration. The first JFET sub-region may comprise an implanted region and the second JFET sub-regions may comprise un-implanted regions. Each well region may have a hexagonal shape when viewed in plan view in some embodiments. Each second JFET sub-region may have a triangular shape when viewed in plan view in some embodiments.

Pursuant to further embodiments of the present invention, methods of fabricating a semiconductor device are provided in which a semiconductor layer structure is formed that includes a drift layer having a first conductivity type. A first patterned mask is formed on an upper surface of the semiconductor layer structure, the first patterned mask exposing portions of the semiconductor layer structure where well regions and source regions will be formed. A series of at least three angled ion implantation steps are performed using different oblique implantation angles using the first patterned mask as an ion implantation mask to implant first conductivity type dopants into the exposed portions of the upper surface of the semiconductor layer structure. Second conductivity type dopants are implanted into the upper surface of the semiconductor layer structure using the first patterned mask as an ion implantation mask to form a plurality of preliminary well regions in the semiconductor layer structure. A second patterned mask is formed on the semiconductor layer structure. First conductivity type dopants are implanted into the upper surface of the semiconductor layer structure using the second patterned mask as an ion implantation mask to convert the preliminary well regions into the well regions having the second conductivity type and to form a plurality of source regions having the first conductivity type within the respective well regions.

In some embodiments, after forming the source regions, the semiconductor device comprises a JFET region that comprises a plurality of spaced-apart first JFET sub-regions that each has a first doping concentration and a second JFET sub-region that has a second doping concentration that is lower than the first doping concentration. In some embodiments, the second JFET sub-region comprises a continuous region that surrounds each of the first JFET sub-regions. In some embodiments, the first JFET sub-regions comprise implanted regions and the second JFET sub-region comprises an un-implanted region. In some embodiments, the plurality of well regions are arranged in columns, where the well regions in adjacent columns are offset from each other in a column direction.

In some embodiments, each well region has a hexagonal shape when viewed in plan view. In some embodiments, each first JFET sub-region has an annular hexagonal shape when viewed in plan view. In some embodiments, each first JFET sub-region surrounds a respective one of the well regions when viewed in plan view. In some embodiments, the first JFET sub-regions are positioned between the well regions and the second JFET sub-region when the semiconductor device is viewed in plan view.

In some embodiments, after forming the source regions, the semiconductor device comprises a JFET region that comprises a plurality of spaced-apart second JFET sub-regions that each has a second doping concentration and a first JFET sub-region that has a first doping concentration that is higher than the second doping concentration. In some embodiments, the second JFET sub-region comprises a continuous region that surrounds each of the first JFET sub-regions. In some embodiments, each of the plurality of spaced-apart second JFET sub-regions has a triangular shape when the semiconductor device is viewed in plan view.

In some embodiments, the first JFET sub-regions comprise implanted regions and the second JFET sub-region comprises an un-implanted region. In some embodiments, the second conductivity type dopants are implanted using a non-angled ion implantation process.

In some embodiments, the plurality of spaced-apart second JFET sub-regions are positioned at centroids of a plurality of triangular regions that have non-constant JFET gaps when the semiconductor device is viewed in plan view.

In some embodiments, the series of at least three angled ion implantation steps comprises at least six ion implantation steps.

Pursuant to still further embodiments of the present invention, methods of fabricating a semiconductor device are provided in which a semiconductor layer structure is formed that includes a drift layer having a first conductivity type. A first patterned mask is formed on an upper surface of the semiconductor layer structure. First conductivity dopants are implanted into the semiconductor layer structure using the first patterned mask as an ion implantation mask. The first patterned mask is expanded to form a second patterned mask. Second conductivity dopants are implanted into the semiconductor layer structure using the second patterned mask as an ion implantation mask to form a plurality of preliminary well regions in the drift layer. The second patterned mask is expanded to form a third patterned mask. First conductivity dopants are implanted into the semiconductor layer structure using the third patterned mask as an ion implantation mask to convert the preliminary well regions into a plurality of well regions and to form a plurality of source regions within the respective well regions.

In some embodiments, after forming the source regions, the well regions comprise longitudinally-extending well regions and a plurality of longitudinally extending JFET regions are provided that are in between respective pairs of adjacent well regions, where portions of each JFET region that contact the well regions are implanted regions while a center portion of each JFET region between the implanted regions is un-implanted.

In some embodiments, the second patterned mask is formed by enlarging the first patterned mask using a spacer process.

In some embodiments, the third patterned mask is formed by enlarging the second patterned mask using a spacer process.

In some embodiments, implanting first conductivity dopants into the semiconductor layer structure using the first patterned mask as an ion implantation mask comprises implanting first conductivity dopants into the semiconductor layer structure using a channeled ion implantation process while using the first patterned mask as an ion implantation mask.

In some embodiments, after forming the source regions, the semiconductor device comprises a JFET region that comprises a plurality of spaced-apart first JFET sub-regions that each has a first doping concentration and a second JFET sub-region that has a second doping concentration that is lower than the first doping concentration. In some embodiments, the second JFET sub-region comprises a continuous region that surrounds each of the first JFET sub-regions. In some embodiments, the first JFET sub-regions comprise implanted regions and the second JFET sub-region comprises an un-implanted region.

In some embodiments, the plurality of well regions are arranged in columns, where the well regions in adjacent columns are offset from each other in a column direction. In some embodiments, each well region has a hexagonal shape when viewed in plan view. In some embodiments, each first JFET sub-region surrounds a respective one of the well regions when viewed in plan view. In some embodiments, the first JFET sub-regions are positioned between the well regions and the second JFET sub-region when the semiconductor device is viewed in plan view.

In some embodiments, after forming the source regions, the semiconductor device comprises a JFET region that comprises a plurality of spaced-apart second JFET sub-regions that each has a second doping concentration and a first JFET sub-region that has a first doping concentration that is higher than the second doping concentration. In some embodiments, the first JFET sub-region comprises a continuous region that surrounds each of the second JFET sub-regions. In some embodiments, the plurality of spaced-apart second JFET sub-regions are positioned at centroids of a plurality of triangular regions that have non-constant JFET gaps when the semiconductor device is viewed in plan view. In some embodiments, the first JFET sub-region comprises an implanted regions and each second JFET sub-region comprises an un-implanted region. In some embodiments, the plurality of well regions are arranged in columns, where the well regions in adjacent columns are offset from each other in a column direction.

### BRIEF DESCRIPTION OF DRAWINGS

FIG. 1 is a semi-log graph illustrating the relationship between the lifetime of the gate oxide layer as a function of applied electric field strength

FIG. 2 is a schematic cross-sectional view of a unit cell of a conventional power MOSFET.

FIG. 3A is a schematic plan view of a top surface of the semiconductor layer structure of a power MOSFET according to embodiments of the present invention.

FIG. 3B is a schematic cross-sectional diagram taken along the line 3B-3B of FIG. 3A with portions of the upper metallization and dielectric layers of the power MOSFET added for context.

FIGS. 4A-4F are schematic cross-sectional diagrams illustrating a first method of fabricating the power MOSFET of FIGS. 3A-3B.

FIGS. 5A-5F are schematic cross-sectional diagrams illustrating a second method of fabricating the power MOSFET of FIG. 4.

FIG. 6A is a schematic plan view of a top surface of the semiconductor layer structure of a modified version of the power MOSFET of FIGS. 3A-3B.

FIG. 6B is a schematic cross-sectional diagram taken along the line 6B-6B of FIG. 6A with portions of the upper metallization and dielectric layers of the power MOSFET added for context.

FIG. 7A is a schematic plan view of a top surface of a semiconductor layer structure of a power MOSFET that can be fabricated using certain methods according to embodiments of the present invention.

FIG. 7B is a schematic cross-sectional diagram taken along the line 7B-7B of FIG. 7A with portions of the upper metallization and dielectric layers of the power MOSFET added for context.

FIGS. 8A-8F are schematic cross-sectional diagrams illustrating a method according to embodiments of the present invention of fabricating the power MOSFET of FIGS. 7A-7B.

FIGS. 9A and 9B are schematic plan views of a top surface of a semiconductor layer structure of a power MOSFET that can be fabricated using a modified version of the method of FIGS. 5A-5F.

FIG. 10 is a schematic plan view of a top surface of the semiconductor layer structure of a power MOSFET according to further embodiments of the present invention that has rectangular cells.

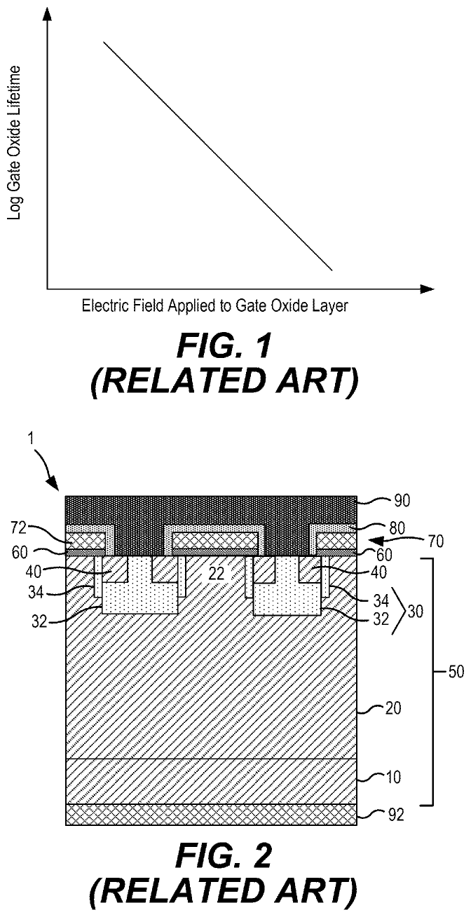

### DETAILED DESCRIPTION

There is an inherent tradeoff in vertical power silicon carbide MOSFETs that have a planar gate design between the on-state resistance and the reliability of the device. As discussed above, the gate oxide layer of a vertical power silicon carbide MOSFET with a planar gate design will ultimately fail if subjected to high electric fields for too much time. One way to improve the reliability of such a device is to reduce the doping concentration in the JFET region of the MOSFET, as the reduced doping concentration acts to weaken the electric fields that extend into the JFET region, thereby reducing the strength of the electric field in the gate oxide layer. However, the reduction in the doping concentration of the JFET region results in a direct increase in the resistance of the MOSFET during on-state operation (which refers to the resistance between the source and gate terminals, which is typically referred to as the “on-state resistance”), as the JFET region is part of the current path between the source and gate terminals. This increase in the on-state resistance increases conduction losses and reduces switching speeds, both of which are undesirable.

The tradeoff between on-state resistance and reliability in a vertical power silicon carbide MOSFET that has a planar gate design can also be adjusted by modifying the width of the JFET gap (i.e., increasing or decreasing the widths of the JFET regions). Increasing the JFET gap advantageously decreases the on-state resistance of the MOSFET, but also disadvantageously decreases the blocking voltage and increases the peak electric field at a center of the JFET region, degrading the reliability of the MOSFET. Decreasing the JFET gap advantageously increases the blocking voltage of the MOSFET and decreases the peak electric fields, but disadvantageously increases the on-state resistance of the MOSFET. Accordingly, both the JFET gap and the doping concentration of the JFET region should be chosen to meet a desired blocking voltage, on-state resistance, and peak electric field for the MOSFET.

One technique that has been suggested for improving the reliability of a vertical power silicon carbide MOSFET that has a planar gate design without causing a large increase in the on-state resistance is to form the portion of the drift region that will later become the JFET region to have a lower doping concentration, and to then selectively implant this portion of the JFET region so that the JFET region includes a first (implanted) portion with a higher doping concentration and a second (un-implanted) portion with a lower doping concentration. The portions of the JFET region that are closest to the p-wells may be implanted to have the higher doping concentration, as these portions of the JFET region have the highest current flow (and hence the increased doping concentration has a greater effect on improving the on-state resistance) while the portions of the JFET region that would normally experience the highest electric field values during reverse blocking operation remain un-implanted, and hence the lower doping concentration in these regions of the MOSFET helps to suppress the electric field strengths in these regions of the device.

U.S. Pat. No. 11,631,762 (“the '762 patent”) discloses a technique for selectively implanting a JFET region in this manner. In the method disclosed in the '762 patent, a first ion implantation process is performed using a patterned ion implantation mask to implant p-type dopants into the drift layer to form the p-wells of the device, and then a pair of angled ion implants are performed using the same ion implantation mask to implant n-type dopants into side portions of each JFET region that are adjacent the p-wells while leaving the center portion of each JFET region un-implanted. This approach selectively implants the JFET region while also self-aligning the JFET implant with the p-wells.

The technique disclosed in the '762 patent requires performing angled ion implantation steps, which complicates the fabrication process and precludes the use of channeled ion implantation techniques. In addition, the angled ion implantations tend to provide a varying dopant profile with depth, as the ions travel at different rates through the mask structure and the semiconductor layer structure, which may result in non-ideal doping profiles. Moreover, the techniques disclosed in the '762 patent are designed for MOSFETs having longitudinally-extending well and source regions and are not suitable for use in MOSFETs having well regions that are formed as a plurality of smaller spaced apart islands within, for example, a continuous JFET region. Power MOSFETs having well regions formed as spaced-apart islands are referred to as having a “cell configuration,” whereas power MOSFETs having conventional longitudinally-extending well and source regions are referred to as having a “stripe configuration.” MOSFETs having cell configurations may provide higher cell (or MOS channel) packing density than MOSFETs having the more conventional stripe configuration.

Pursuant to embodiments of the present invention, improved methods are provided for forming vertical power silicon carbide MOSFETs (and other power semiconductor devices, such as IGBTs). Pursuant to some of these methods, both stripe and cell configuration vertical power silicon carbide MOSFETs may be formed that have selective JFET implants that are self-aligned with the well regions of the device without the need for angled ion implantation steps. Pursuant to further of these methods, cell configuration vertical power silicon carbide MOSFETs may be formed that have selective JFET implants that are self-aligned with the well regions of the device. In addition, improved cell configuration vertical power silicon carbide MOSFETs are provided.

Pursuant to some embodiments of the present invention, semiconductor devices such as a MOSFET or IGBT are provided that comprise a semiconductor layer structure that includes a drift layer having a first conductivity type, a JFET region that has the first conductivity type in the upper portion of the drift layer, a plurality of well regions having a second conductivity type in an upper portion of the drift layer, each well region forming a respective island within the JFET region when viewed in plan view, and a plurality of source regions having the first conductivity type, where each source region is within a respective one of the well regions. The JFET region comprises a plurality of spaced-apart first JFET sub-regions that each has a first doping concentration and a second JFET sub-region that has a second doping concentration that is lower than the first doping concentration, and the second JFET region extend arounds at least one of the first JFET sub-regions when viewed in plan view. Additionally or alternatively, the second JFET region may extend around at least one of the well regions when viewed in plan view.

Pursuant to further embodiments of the present invention, semiconductor devices are provided that comprise a semiconductor layer structure that includes a drift layer having a first conductivity type, a JFET region that has the first conductivity type in the upper portion of the drift layer, a plurality of well regions having a second conductivity type in an upper portion of the drift layer, each well region forming a respective island within the JFET region when viewed in plan view, and a plurality of source regions having the first conductivity type, where each source region is within a respective one of the well regions. The JFET region comprises a continuous first JFET sub-region that extends around the plurality of well regions and that has a first doping concentration and a plurality of spaced-apart second JFET sub-regions that each has a second doping concentration, where the second doping concentration is lower than the first doping concentration.

The first JFET sub-region may be an implanted region and the second JFET sub-regions may be un-implanted regions. Each well region may have a hexagonal shape when viewed in plan view. Each second JFET sub-region may have a triangular shape when viewed in plan view.

Pursuant to further embodiments of the present invention, methods for forming vertical power silicon carbide semiconductor devices are provided in which a semiconductor layer structure is formed that includes a drift layer having a first conductivity type. A first patterned mask is formed on an upper surface of the semiconductor layer structure that exposes portions of the semiconductor layer structure where well regions and source regions will be formed in later processing steps. A series of at least three angled ion implantation steps are then performed using different oblique implantation angles using the first patterned mask as an ion implantation mask to implant first conductivity type dopants into the upper surface of the semiconductor layer structure. Second conductivity type dopants are implanted into the upper surface of the semiconductor layer structure using the first patterned mask as an ion implantation mask to form a plurality of preliminary well regions in the semiconductor layer structure. A second patterned mask is formed on the semiconductor layer structure. First conductivity type dopants are then implanted into the upper surface of the semiconductor layer structure using the second patterned mask as an ion implantation mask to convert the preliminary well regions into the well regions having the second conductivity type and to form a plurality of source regions having the first conductivity type within the respective well regions.

The completed semiconductor device includes a JFET region. In some embodiments, the JFET regions comprises a plurality of spaced-apart implanted first JFET sub-regions that each has a first doping concentration and a continuous, un-implanted second JFET sub-region that has a second doping concentration that is lower than the first doping concentration. The second JFET sub-region may surround each of the first JFET sub-regions. The well regions may be arranged in columns, where the well regions in adjacent columns are offset from each other in a column direction. Each well region may have a hexagonal shape when viewed in plan view. Each first JFET sub-region may have an annular hexagonal shape when viewed in plan view and/or may surround a respective one of the well regions when viewed in plan view.

In other embodiments, the JFET region may comprise a plurality of spaced-apart second JFET sub-regions that each has a second doping concentration and a continuous first JFET sub-region that has a first doping concentration that is higher than the second doping concentration. The second JFET sub-region may surround each of the first JFET sub-regions. In some cases, each of the second JFET sub-regions may have a triangular shape when the semiconductor device is viewed in plan view. The plurality of spaced-apart second JFET sub-regions may be positioned at centroids of a plurality of triangular regions that have non-constant JFET gaps when the semiconductor device is viewed in plan view.

Pursuant to further embodiments of the present invention, methods for forming vertical power silicon carbide semiconductor devices are provided in which a semiconductor layer structure is formed that includes a drift layer having a first conductivity type. A first patterned mask is formed on an upper surface of the semiconductor layer structure. First conductivity dopants are implanted into the semiconductor layer structure using the first patterned mask as an ion implantation mask. The first patterned mask is expanded to form a second patterned mask. Second conductivity dopants are implanted into the semiconductor layer structure using the second patterned mask as an ion implantation mask to form a plurality of preliminary well regions in the drift layer. The second patterned mask is expanded to form a third patterned mask. First conductivity dopants are implanted into the semiconductor layer structure using the third patterned mask as an ion implantation mask to convert the preliminary well regions into a plurality of well regions and to form a plurality of source regions within the respective well regions. The second patterned mask may be formed by enlarging the first patterned mask using a spacer process, and/or the third patterned mask may be formed by enlarging the second patterned mask using a spacer process.

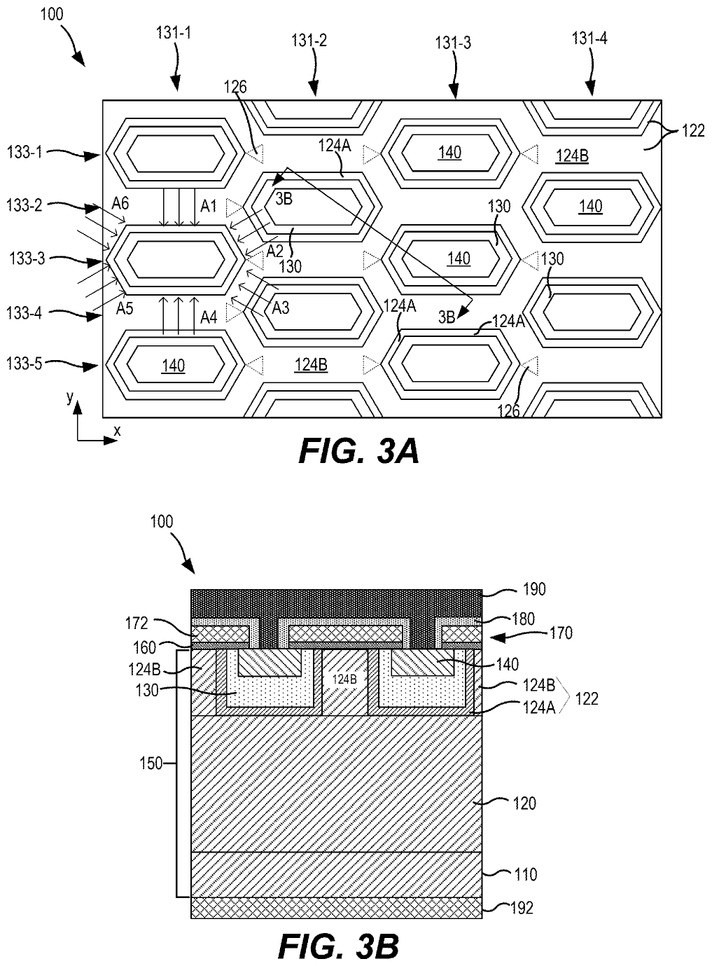

Example embodiments of power semiconductor devices according to embodiments of the present invention will now be described with reference to FIGS. 3A-10. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate controlled thyristors and the like.

FIG. 3A is a schematic plan view of a top surface of a semiconductor layer structure of a power MOSFET 100 according to embodiments of the present invention. In FIG. 3A, the upper polysilicon, metal and dielectric layers are omitted so that the upper surface of the silicon carbide semiconductor layer structure of the MOSFET is visible. FIG. 3B is a schematic cross-sectional diagram of the power MOSFET 100 taken along line 3B-3B of FIG. 3A with the upper silicon, metal and dielectric layers of power MOSFET 100 are added for context. It will be appreciated that the thicknesses of various of the layers and regions in FIGS. 3A-3B are not necessarily drawn to scale. The same is true with respect to the other figures included in this application.

Referring first to FIG. 3B, the power MOSFET 100 includes an n-type silicon carbide semiconductor substrate 110 such as, for example, a single crystal 4H silicon carbide semiconductor substrate that is heavily-doped with n-type impurities. The n-type doping concentration of the substrate 110 may be, for example, between 1×10¹⁸ atoms/cm⁻³ and 1×10²¹ atoms/cm⁻³, although other doping concentrations may be used. Herein, the “doping concentration” of a semiconductor material refers to the number of dopant atoms that cause the semiconductor material to have a certain conductivity type (i.e., either n-type or p-type) that are present within a cubic centimeter of semiconductor material as measured using standard measurement techniques such as Secondary Ion Mass Spectrometry (“SIMS”). For an n-type semiconductor material, references to the doping concentration refer to the concentration of n-type dopants and for a p-type semiconductor material, references to the doping concentration refer to the concentration of p-type dopants. The substrate 110 may be any appropriate thickness (e.g., between 100 and 500 microns thick), and it will be appreciated that the substrate 110 will typically be much thicker than shown. The thickness of various other layers of power MOSFET 100 likewise may not be shown to scale in order to allow other portions of the devices to be enlarged in the figures. The substrate 110 may be partially or fully removed in some embodiments.

A lightly-doped n-type silicon carbide drift region 120 is provided on the upper surface of the substrate 110. The n-type silicon carbide drift region 120 may be formed by, for example, epitaxial growth on the silicon carbide substrate 110. The n-type silicon carbide drift region 120 may have, for example, a doping concentration of 1×10¹⁴ to 5×10¹⁶ dopants/cm⁻³. The doping concentration may vary with the voltage blocking rating of the device, with devices having higher voltage blocking ratings typically having lower doping concentrations in the drift region 120. For example, a MOSFET having a voltage blocking rating of 10 kV or more might have a drift region n-type doping concentration of between 1×10¹⁴ to 5×10¹⁴ dopants/cm⁻³, whereas a MOSFET having a voltage blocking rating of 500-1200 V might have a drift region n-type doping concentration of between 1×10¹⁶ to 5×10¹⁶ dopants/cm⁻³. The n-type silicon carbide drift region 120 may be a thick region, having a vertical height above the substrate 110 of, for example, 3-50 microns. While not shown in the figures, in some embodiments, an upper portion of the n-type silicon carbide drift region 120 may be more heavily doped than the remainder of the drift region 120 to provide a current spreading layer in an upper portion of the drift region 120. The doping concentration of this current spreading layer may be, for example, about 1.5 to 4.0 times higher than the doping concentration of the remainder of the drift region 120. The current spreading layer may be formed during the epitaxial growth process. Herein, the current spreading layer, if provided, is considered to be part of the drift layer 120 and hence will not be discussed separately.

A plurality of p-type well regions 130 (which may also be referred to herein as “p-wells 130”) are formed in upper portions of the n-type drift region 120. As shown best in FIG. 3A, the p-wells 130 may be arranged in columns 131 (four columns of p-wells 130 are shown in FIG. 3A), where each column extends in the y-direction. The p-wells 130 are also aligned in rows 133, where each row 133 extends in the x-direction (which is perpendicular to the y-direction). As shown in FIG. 3A, the p-wells 130 in adjacent columns 131 are offset from each other in the column (y) direction. Consequently, the p-wells 130 in the first and third columns 131-1, 131-3 are aligned in rows 133-1, 133-3 and 133-5, while the p-wells 130 in the second and fourth columns 131-2, 131-4 are aligned rows 133-2, 133-4, with the p-wells 130 in the second and fourth columns 131-2, 131-4 offset in the column (y) direction by about half the center-to-center distance between the p-wells 130 in the first, third and fifth columns 131-1, 131-3, 131-5. As shown in FIG. 3A, each p-well 130 may have a hexagonal shape when viewed in plan view (i.e., from directly above), and the p-wells 130 may comprise a plurality of islands in the JFET region 122. In the depicted embodiment, each p-well 130 defines an irregular hexagon when viewed in plan view, where two sides of the hexagon are longer than the other four sides of the hexagon.

Each p-well 130 may have a doping concentration of, for example, between 5×10¹⁵ cm⁻³ and 5×10¹⁹ cm⁻³ and, more typically, between 5×10¹⁶ cm⁻³ and 5×10¹⁹ cm⁻³. The p-wells 130 may be formed via ion implantation. As known to those skilled in the art, ions such as n-type or p-type dopants may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may penetrate into the semiconductor layer. The ions will implant at different depths into the semiconductor layer so that the predetermined kinetic energy will provide an implant “profile” with varying ion concentrations as a function of depth. The dopants may comprise, for example, Al⁺ or N⁺ ions, although any appropriate dopant ions may be used. In some embodiments, the implantation may be performed at different temperatures such as, for example, temperatures of 75° C. or more. It will be appreciated that the p-wells 130 typically have a doping concentration that varies with depth, with upper outer portions of the p-wells 130 being less heavily doped than bottom portions of the p-wells 130. Thus, at least the outer portions of the p-wells 130 will typically have a graded p-type doping profile with the doping concentration increasing with increasing depth. This allows the channel regions to be doped to an ideal value (which is typically a lighter doping) while allowing the bottom portions of the p-wells 130 to be more heavily doped p-type to enhance the electric field blocking properties thereof.

A JFET region 122 is defined in the upper portion of the drift region 120 in the region in between the p-wells 130. The JFET region 122 may comprise a continuous region as shown in FIG. 3A. The portions of the p-wells 130 that are visible in the plan view of FIG. 3A may act as channel regions 134 for MOSFET 100, as will be discussed in greater detail below. The JFET region 122 includes a plurality of first JFET sub-regions 124A and a continuous second JFET sub-region 124B, as will be described in greater detail below. The first JFET sub-regions 124A may be implanted regions that are formed via ion implantation, while the second JFET sub-region 124B may be an un-implanted region.

Heavily-doped n-type silicon carbide source regions 140 are formed in upper portions of the p-wells 130. The source regions 140 may have a doping concentration of, for example, between 5×10¹⁸ cm⁻³ and 5×10²¹ cm⁻³. The source regions 140 are typically formed via ion implantation. The substrate 110, the drift region 120 (including the JFET region 122 and any current spreading layer), the p-wells 130 and the source regions 140 together comprise a semiconductor layer structure 150 of MOSFET 100.

As shown in FIG. 3B, a patterned gate dielectric layer 160 is formed on the upper surface of the semiconductor layer structure 150. The gate insulating layer 160 may comprise, for example, a silicon oxide layer, although other insulating materials may be used. A gate electrode layer 170 that includes a plurality of gate electrodes 172 is formed on the gate insulating layer 160. The gate electrode layer 170 may comprise, for example, a conductive material such as polysilicon, a silicide or a metal. An intermetal dielectric layer 180 may cover the gate electrode layer 170. The intermetal dielectric layer 180 may comprise, for example, a silicon oxide layer. A plurality of openings 182 extend through the gate insulating layer 160, the gate electrode layer 170 and the intermetal dielectric layer 180 to expose the upper surfaces of the n-type source regions 140. A source metallization layer 190 is formed over the intermetal dielectric layer 180 and into the openings 182 so that the source metallization layer 190 makes electrical contact to the of the n-type source regions 140 while being electrically insulated from the gate electrode layer 170. The source metallization layer 190 may comprise, for example, metals such as nickel, titanium, tungsten and/or aluminum, and/or alloys and/or thin layered stacks of these and/or similar materials. A drain contact 192 may be formed on the lower surface of the substrate 110. The drain contact 192 may comprise, for example, the same or similar materials to the source metallization layer 190, and may form an ohmic contact to the silicon carbide substrate 110.

While not shown in the figures, typically each p-well 130 will include a highly-doped sub-region that extends to the upper surface of the semiconductor layer structure 150 to contact the source metallization layer 190, thereby forming a low resistivity connection between the p-well 130 and the source metallization layer 190. For example, such a highly-doped sub-region may be provided that extends upwardly through the middle of each source region 140. Since these highly-doped sub-regions are conventional they are not shown in the figures herein, but it will be appreciated that such highly-doped sub-regions may be provided in each p-well 130 (and in the p-wells of the other semiconductor devices according to embodiments of the present invention that are described herein.

As discussed above, during reverse blocking operation, strong electric fields extend upwardly into the semiconductor layer structure 150 from the drain contact 192. The p-wells 130 act to block these electric fields, and hence the electric fields primarily extend into the JFET regions 122, with the electric fields being strongest in portions of the JFET regions 122 that are farthest from the p-wells 130. In a MOSFET having a conventional stripe configuration, each JFET region comprises a longitudinally-extending stripe that extends in between a pair of adjacent p-wells, where the width of each JFET region (which is referred to as the “JFET gap”) is constant. In such a device, the electric field will be the strongest in the middle of each JFET region.

The MOSFET 100 of FIGS. 3A-3B, in contrast, has a cell configuration as the p-wells 130 (with source regions 140 formed therein) are formed as a series of islands in the JFET region 122. While the JFET gap is constant in between portions of adjacent p-wells 130 that have parallel sidewalls, there are also a plurality of triangular shaped regions 126 (shown using dotted lines) where the JFET gap is not constant. Due to the shapes of the p-wells 130 and the distances between adjacent p-wells 130, the electric fields during reverse blocking operation tend to be strongest in these triangular shaped regions 126 (and stronger than the strongest electric fields that form in between in portions of adjacent p-wells 130 that have parallel sidewalls). The strongest electric fields occurring at the centroid of each triangular area 126. As discussed above, the increased electric field strength may degrade the gate dielectric layer 160 over time, potentially impacting the reliability of MOSFET 100.

Typically, the JFET region of a power silicon carbide MOSFET is a uniformly doped region. However, as discussed in U.S. Pat. No. 11,075,295 (“the '295 patent”), the entire content of which is incorporated herein by reference, when the JFET gap is not constant, it may be advantageous to form the JFET region to have a non-uniform doping concentration so that portions of the JFET region that would otherwise experience higher electric fields during reverse blocking operation have a reduced doping concentration as compared to the remainder of the JFET region. The reduced doping concentration acts to weaken the strength of the electric fields during reverse blocking operation in these portions of the JFET region, which may extend the lifetime of the gate oxide layer. One potential issue with the technique disclosed in the '295 patent is that an ion implantation mask having triangular islands is used during the JFET implant, and these triangular islands may have very narrow features (e.g., about 1 micron) that need to be aligned with the p-wells. As such, unintended process variations may result in misalignment of the implanted and un-implanted portions of the JFET region from what was intended, which may adversely affect the on-state resistance performance and/or the reliability of the MOSFET if such unintended process variations occur.

Referring again to FIGS. 3A-3B, it can be seen that the JFET region 122 of MOSFET 100 includes the plurality of spaced-apart first JFET sub-regions 124A and a continuous second JFET sub-region 124B. Each of the first JFET sub-regions 124A has a first doping concentration and the second JFET sub-region 124B has a second doping concentration that is less than the first doping concentration. In the depicted embodiment, the second JFET sub-region 124B comprises most of the JFET region 122 and the first JFET sub-regions 124A are much smaller and each have an annular hexagonal shape when viewed in plan view. In one example embodiment, the doping concentration of each first JFET sub-region 124A is between 1×10¹⁶ cm⁻³ and 2×10¹⁷ cm⁻³ and the doping concentration of the second JFET sub-region 124B is between 1×10¹⁵ cm⁻³ and 5×10¹⁶ cm⁻³. In other embodiments, the doping concentration of the first JFET sub-region 124A may be between 2×10¹⁶ cm⁻³ and 2×10¹⁷ cm⁻³, between 3×10¹⁶ cm⁻³ and 2×10¹⁷ cm⁻³, between 4×10¹⁶ cm⁻³ and 2×10¹⁷ cm⁻³, between 5×10¹⁶ cm⁻³ and 2×10¹⁷ cm⁻³, between 6×10¹⁶ cm⁻³ and 2×10¹⁷ cm⁻³, between 7×10¹⁶ cm⁻³ and 2×10¹⁷ cm⁻³, between 8×10¹⁶ cm⁻³ and 2×10¹⁷ cm⁻³, between 9×10¹⁶ cm⁻³ and 2×10¹⁷ cm⁻³, between 1×10⁷ cm⁻³ and 2×10¹⁷ cm⁻³, between 2×10¹⁶ cm⁻³ and 1×10¹⁷ cm⁻³, between 2×10¹⁶ cm⁻³ and 9×10¹⁶ cm⁻³, between 2×10¹⁶ cm⁻³ and 8×10¹⁶ cm⁻³, between 2×10¹⁶ cm⁻³ and 7×10¹⁶ cm⁻³, between 2×10¹⁶ cm⁻³ and 6×10¹⁶ cm, between 2×10¹⁶ cm⁻³ and 5×10¹⁶ cm⁻³, between 2×10¹⁶ cm⁻³ and 4×10¹⁶ cm⁻³, and between 2×10¹⁶ cm⁻³ and 3×10¹⁶ cm⁻³. In these embodiments, the doping concentration of the second JFET sub-region 124B may be between 2×10¹⁵ cm⁻³ and 5×10¹⁶, between 3×10¹⁵ cm⁻³ and 5×10¹⁶, between 4×10¹⁶ cm⁻³ and 5×10¹⁶, between 5×10¹⁵ cm⁻³ and 5×10¹⁶, between 6×10¹⁵ cm⁻³ and 5×10¹⁶, between 7×10¹⁵ cm⁻³ and 5×10¹⁶, between 8×10⁵ cm⁻³ and 5×10¹⁶, between 9×10¹⁵ cm⁻³ and 5×10¹⁶, between 1×10¹⁶ cm⁻³ and 5×10¹⁶, between 2×10¹⁶ cm⁻³ and 5×10¹⁶, between 3×10¹⁶ cm⁻³ and 5×10¹⁶, between 4×10¹⁶ cm⁻³ and 5×10¹⁶, between 2×10¹⁵ cm⁻³ and 4×10¹⁶, between 2×10¹⁵ cm and 3×10¹⁶, between 2×10¹⁵ cm⁻³ and 2×10¹⁶, between 2×10¹⁵ cm⁻³ and 1×10¹⁶, between 2×10¹⁵ cm⁻³ and 9×10¹⁵, between 2×10¹⁵ cm⁻³ and 8×10¹, between 2×10¹⁵ cm⁻³ and 7×10¹⁵, between 2×10¹⁵ cm⁻³ and 6×10¹⁵, between 2×10¹⁵ cm⁻³ and 5×10¹⁵, between 2×10¹⁵ cm⁻³ and 4×10¹⁵, between 2×10¹⁵ cm⁻³ and 3×10¹⁵. MOSFETs according to embodiments of the present invention may have any combination of the doping concentrations for the first JFET sub-regions 124A and the second JFET sub-region 124B listed above so long as the doping concentration of the first JFET sub-region 124A exceeds the doping concentration of the second JFET sub-region 124B. The lower doping concentration in the second JFET sub-region 124B acts to reduce the maximum strength of the electric field during reverse blocking operation.

In an example embodiment, the first JFET sub-regions 124A may be implanted regions (i.e., portions of the drift region 120 into which additional n-type dopants are implanted via ion implantation) while the second JFET sub-region 124B may be un-implanted region that has the same doping concentration as the drift layer 120 as originally grown. The doping concentration in the JFET region 122 may transition abruptly between the first JFET sub-region 124A and the second JFET sub-region 124B, or may transition gradually in, for example, a linear, exponential or step-wise manner.

While the doping concentration of the JFET region 122 has a strong effect on the on-state resistance of MOSFET 100, the effect of the JFET region 122 on the on-state resistance is driven by the sub-regions 124A of the JFET region 122 that are in between the parallel sidewalls of adjacent p-wells 130 (particularly if these regions are not made narrow), as during on-state operation the current will primarily flow through these regions as they are closer to the channel regions 134. Thus, the selective doping of the JFET region 122 may improve the reliability of MOSFET 100 by reducing the electric field levels in the gate dielectric layer 160 during reverse blocking operation without having a large impact on the on-state resistance.

Typically, the doping of the JFET region of a MOSFET is set so that the MOSFET will have a favorable balance between the on-state resistance thereof and the electric field levels in the gate dielectric layer during reverse blocking operation. Unfortunately, unintended process variations due to manufacturing tolerances and other factors may result in the size JFET gaps of a MOSFET varying from intended values. For example, if the distance between adjacent p-wells is reduced by 20%, then this reduction may result in perhaps a 20% increase in the on-state resistance. However, as discussed in the '762 patent, if the implanted portions of a selectively implanted JFET region are self-aligned with the p-wells, then any unintended variation in the JFET gap may only act to reduce the size of the un-implanted portion of the JFET region. Since this sub-region of the JFET region may be doped much lower (e.g., an order of magnitude lower) than the implanted sub-regions of the JFET region, the impact of the process variation on the on-state resistance may be greatly reduced.

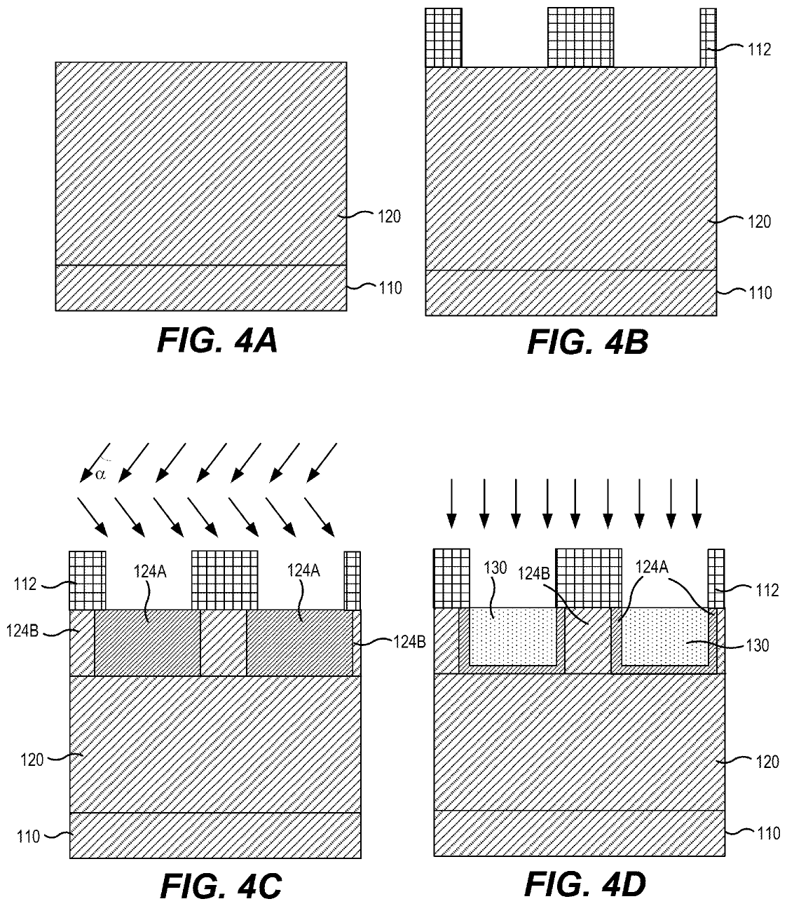

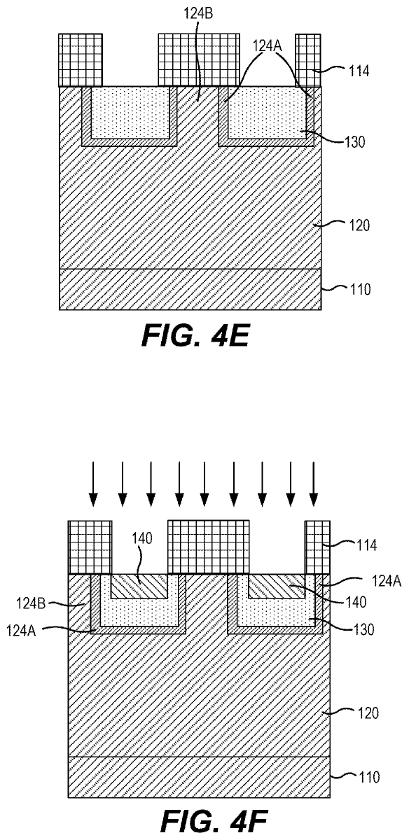

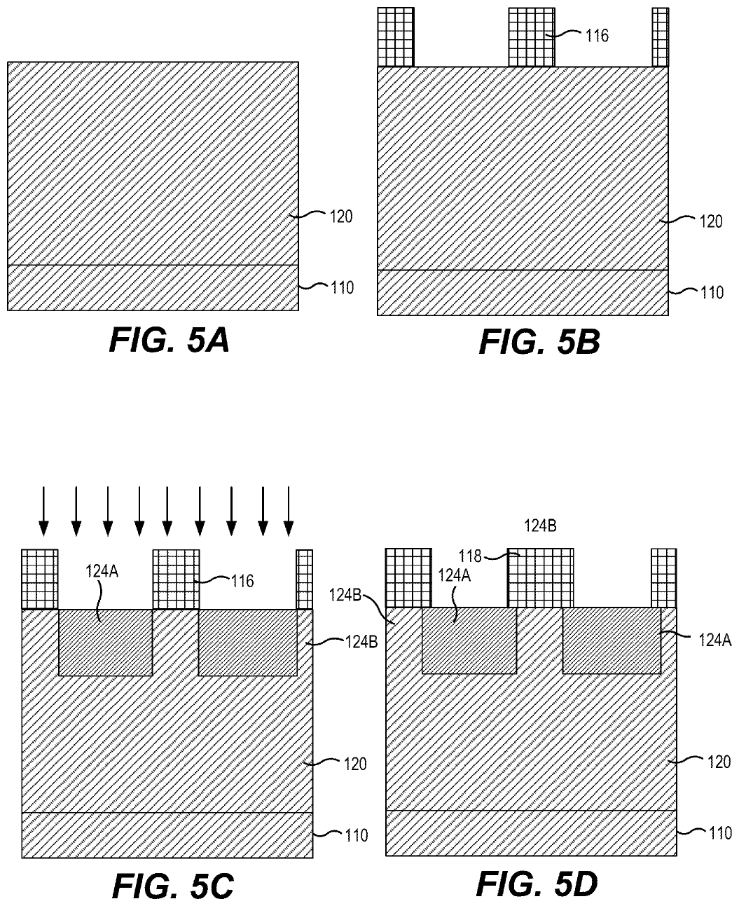

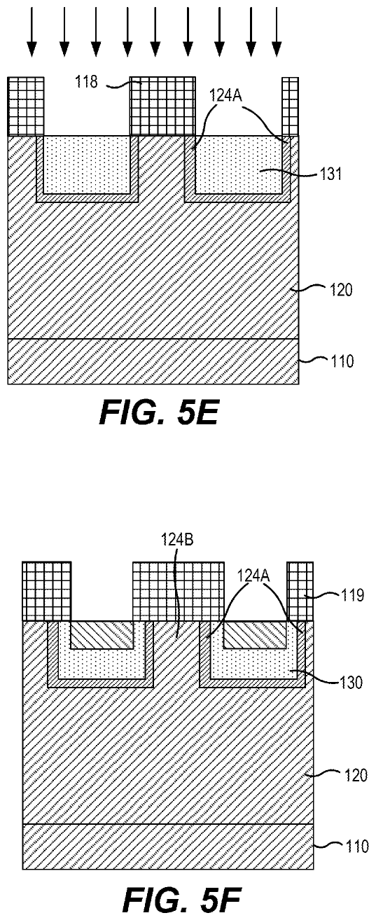

Pursuant to some embodiments of the present invention, methods are provided for forming power silicon carbide MOSFETS that have selectively implanted JFET regions in which the implanted sub-regions of the JFET region are self-aligned with the p-wells. In some embodiments of these methods, the implanted sub-region of the JFET region is formed using a series of angled ion implantations, as will be discussed below with reference to FIGS. 4A-4F. In other embodiments, spacer processes and a non-angled (standard) ion implantation may be used to implant selected portions of the JFET region, as is described below with reference to FIGS. 5A-5F.

FIGS. 4A-4F are schematic cross-sectional diagrams illustrating a first method of fabricating the power MOSFET 100 of FIGS. 3A-3B using a series of angled ion implantation steps to selectively implant the JFET region 122 thereof. The cross-sections of FIGS. 4A-4F are taken along line 3B-3B of FIG. 3A.

Referring to FIG. 4A, the n-type silicon carbide drift layer 120 is epitaxially grown on the heavily-doped n-type silicon carbide substrate 110. The drift layer 120 may be doped n-type during the epitaxial growth process.

Referring to FIG. 4B, an ion implantation mask (e.g., a silicon oxide mask) is formed on the upper surface of the drift layer 120 and then patterned to form a first patterned mask 112 that exposes regions where the p-wells 130 and source regions 140 will be formed in later processing steps. Referring to FIG. 3A, the first patterned mask 112 may exactly cover the region that will become the JFET region 122 of the MOSFET 100, leaving the regions of the drift layer 120 that will later be converted into the p-wells 130 and source regions 140 exposed.

Referring to FIG. 4C, next a series of angled ion implantation process are performed to implant n-type dopants into the upper surface of the drift layer 120. An angled ion implantation process refers to an ion implantation process in which the ions are accelerated toward the surface to be implanted at an oblique angle (i.e., an angle of other than 90⁰ or a multiple of 90°) into the semiconductor layer structure 150. The implant angle α is defined as the angle at which the ions are implanted from an axis that is perpendicular to the upper surface of the device, as shown in FIG. 3C. In some embodiments, the implant angle α may be small, such as between 15 and 30 degrees. In other embodiments, the implant angle α may be larger, such as between 24 and 45 degrees. In example embodiments, a series of six ion implantation processes may be performed, where each angled ion implantation process is performed in a direction that is toward a respective one of the sidewalls of the p-wells. The directions of the six each angled ion implantation processes are shown by the sets of arrows labelled A1-A6 in FIG. 3A. As shown in FIG. 4C, since angled ion implantation processes are used, the n-type dopants are not only implanted into the portions of the drift layer exposed by the first patterned mask 112, but also underneath outer portions of the first patterned mask 112. The extent to which dopant ions are implanted underneath the first patterned mask 112 can be controlled by the energy of the implant process and the angle of the angled ion implantation. The ion implantation steps are designed so that the first JFET sub-regions 124A that are implanted with n-type dopants and are underneath outer portions of the patterned mask 112 and so that the un-implanted second JFET sub-region 124B is underneath an inner portion of the first patterned mask 112.

Referring to FIG. 4D, next, a vertical (i.e., non-angled) ion implantation process is performed using the first patterned mask 112 to implant p-type dopants into the exposed portions of the drift layer 120 to form preliminary p-wells 131. While these regions of the drift layer 120 were doped with n-type dopants during the above-described angled ion implantation processes, the preliminary p-wells 131 are doped much more heavily than the implanted first sub-region 124A of the JFET region 122 so that n-type dopants are overwhelmed by the p-type dopants (and additional p-type dopants may be implanted, if necessary, to counteract the previously implanted n-type dopants). Since the JFET implant and the p-well implant are performed using the same patterned mask 112, the implanted first JFET sub-region 124A is necessarily aligned with the preliminary p-wells 131. Consequently, any unintended variation in the distance between two preliminary p-wells 131 due to processing tolerances will only impact the width of the un-implanted second JFET sub-region 124B of the JFET region 122. As discussed above, this may greatly reduce the impact that such unintended process variations have on the on-state resistance of MOSFET 100.

Referring to FIG. 4E, next a spacer process is used to widen the first patterned mask 112 to convert it into a second patterned mask 114. The spacer process may comprise, for example, depositing an insulating layer such as an oxide or nitride based insulating layer on the existing (original) patterned mask, and then etching the resulting structure in a manner that removes portions of the insulating layer that are deposited in the openings in the original patterned mask while largely leaving intact the portions of the insulating layer that are formed on the sidewalls of the openings in the original patterned mask. In this manner, the openings in the original patterned mask may be narrowed in a controlled manner to provide a new patterned mask that has smaller openings. The spacer process may widen the first patterned mask 112 to cover outer portions of the preliminary p-wells 131 while leaving exposed the regions of the preliminary p-wells 131 that are to be converted into the source regions 140 in a later processing step exposed.

Referring to FIG. 4F, next, a standard vertical ion implantation process is performed to implant n-type dopants into portions of the preliminary p-wells 131 that are exposed by the second patterned mask 114 to convert the upper portions of the exposed portions of the preliminary p-wells 131 into the n-type source regions 140 and to convert the preliminary p-wells 131 into the p-wells 130. The second patterned mask 114 is then removed.

Referring to FIG. 3B, the gate dielectric layer 160, gate electrode layer 170, intermetal dielectric layer 180 and source metallization layer 190 are formed on the upper surface of the semiconductor layer structure 150, and the drain contact 192 is formed on the lower surface of the semiconductor layer structure 150. These layers may be formed in conventional fashion and hence description of the fabricating steps used to form these layers will be omitted here.

Referring again to FIG. 3A, it can be seen that the implanted first JFET sub-regions 124A have annular hexagonal shapes when viewed in plan view, thereby forming more highly doped n-type regions (as compared to the drift layer 120) directly adjacent the channel regions that are formed in the outer portion of each p-well 130. This provides a less resistive path for the current flow during on-state operation, and hence reduces the on-state resistance as compared to a power MOSFET that did not include an implanted JFET region. However, since the continuous second JFET region 124B is un-implanted, it acts to reduce the magnitude of the electrical fields that extend upwardly in between the p-wells 130, thus helping to protect the gate oxide layer 160 from strong electric fields during reverse bias operation.

The maximum on-state resistance that is acceptable for MOSFET 100 may depend upon the intended application for MOSFET 100. If a lower on-state resistance is required, then the implant energies used during the tilted ion implantation steps shown in FIG. 4C may be increased and/or the angle α used during these tilted implants may be increased in order to increase the size of each first JFET sub-region 124A and to decrease the size of the second JFET region 124B. Conversely, if higher reliability is required, then the implant energies and/or the implant angle α may be decreased in order to enlarge the un-implanted second JFET sub-region 124B.

FIGS. 5A-5F are schematic cross-sectional diagrams illustrating a second method of fabricating the power MOSFET of FIGS. 3A-3B. The method shown in FIGS. 5A-5F does not use tilted ion implants and hence may be simpler to perform in practice as compared to the method of FIGS. 4A-4F.

Referring to FIG. 5A, the n-type silicon carbide drift layer 120 is epitaxially grown on the heavily-doped n-type silicon carbide substrate 110. The drift layer 120 may be doped n-type during the epitaxial growth process.

Referring to FIG. 5B, an ion implantation mask layer (e.g., a silicon oxide mask) is formed on the upper surface of the drift layer 120 and then patterned to form a first patterned mask 116 that exposes regions where the first JFET sub-regions 124A, the p-wells 130 and the source regions 140 will be formed. Referring to FIG. 3A, the first patterned mask 116 may exactly cover the region that will become the second JFET sub-region 124B of the MOSFET 100.

Referring to FIG. 5C, next, a vertical (i.e., non-angled) ion implantation process is performed using the first patterned mask 116 to selectively implant n-type dopants into the upper surface of the drift layer 120. This ion implantation step is used to implant the portions of the semiconductor layer structure 150 that will ultimately form the first JFET sub-regions 124A, the p-wells 130 and the source regions 140. The portions of the semiconductor layer structure 150 that will ultimately become the second JFET sub-region 124B is shielded by the first patterned mask 116 and hence is not implanted with additional n-type dopants.

Referring to FIG. 5D, next, a first spacer process is used to widen the first patterned mask 116 to convert it into a second patterned mask 118. The first spacer process may, for example, be the same spacer process described above with reference to FIG. 4E. Outer portions of the second patterned mask 118 cover the portions of the semiconductor layer structure 150 that will ultimately form the first JFET sub-regions 124A.

Referring to FIG. 5E, next, a standard ion implantation process is performed to implant p-type dopants into the exposed surfaces of the semiconductor layer structure 150 in order to form preliminary p-wells 131.

Referring to FIG. 5F, next, a second spacer process is used to widen the second patterned mask 118 to convert it into a third patterned mask 119. The second spacer process may, for example, be the same spacer process described above with reference to FIG. 4E. The outer portion of the third patterned mask 119 may cover the entirety of the semiconductor layer structure 150 in the active region of the MOSFET 100 except for the portions of the device that will ultimately be the source regions 140. Then, a standard ion implantation process is performed to implant n-type dopants into the exposed surfaces of the semiconductor layer structure 150 in order to form the source regions 140, which also has the effect of converting the preliminary p-wells 131 into the p-wells 130. The third patterned mask 119 is then removed.

Referring to FIG. 3B, the gate dielectric layer 160, gate electrode layer 170, intermetal dielectric layer 180 and source metallization layer 190 are formed on the upper surface of the semiconductor layer structure 150, and the drain contact 192 is formed on the lower surface of the semiconductor layer structure 150. These layers may be formed in conventional fashion and hence description of the fabricating steps used to form these layers will be omitted here

As described above, the method of FIGS. 4A-4F or the method of FIGS. 5A-5F may be used to form the MOSFET 100 of FIGS. 3A-3B. The method of FIGS. 5A-5F advantageously does not include any tilted ion implantation processes and hence may be easier to implement in practice.

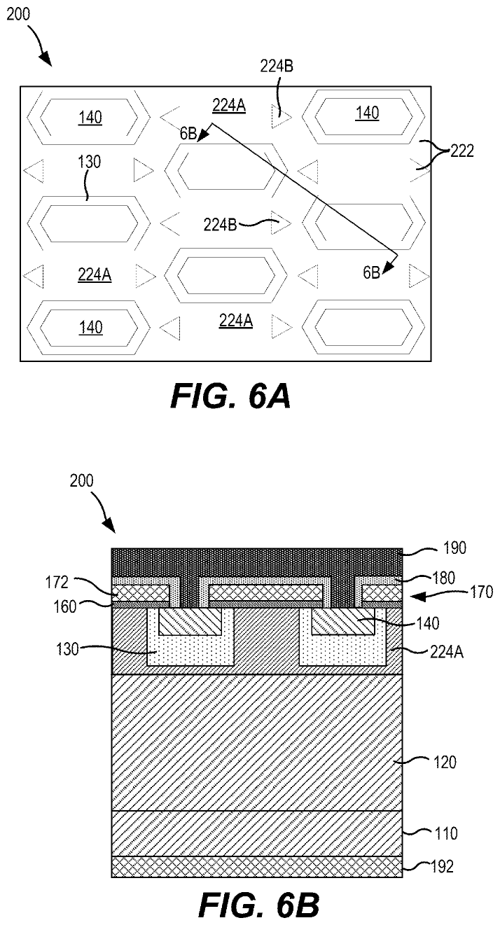

FIG. 6A is a schematic plan view of a top surface of the semiconductor layer structure of a MOSFET 200 that is modified version of the power MOSFET of FIGS. 3A-3B. FIG. 6B is a schematic cross-sectional diagram taken along the line 6B-6B of FIG. 6A with portions of the upper metallization and dielectric layers added for context. The MOSFET 200 is very similar to MOSFET 100, and hence the description below will focus on the differences between the two MOSFETS 100, 200.

As shown in FIG. 6A, the only difference between MOSFET 200 and MOSFET 100 is that each of the first JFET sub-regions 124A in MOSFET 100 is widened in MOSFET 200 so that in MOSFET 200 the first JFET sub-regions 124A of MOSFET 100 merge together to form one larger, continuous first JFET sub-region 224A in MOSFET 200. As a result, MOSFET 200 includes a plurality of smaller, spaced-apart second JFET sub-regions 224B that each have a triangular shape. The spaced-apart second JFET sub-regions 224B are located in the triangular regions 126 of MOSFET 100 that are discussed above with reference to FIG. 3A. As noted in the discussion above, these triangular regions 126 are the locations where the strongest electric fields would appear if the entire JFET region 222 of the MOSFET 200 had a constant n-type doping concentration.

MOSFET 200 may be a good choice for applications that have more stringent on-state resistance requirements, since most of the JFET region 222 thereof is implanted with additional n-type dopants to form the large, continuous first JFET sub-region 224A. However, since the portions of the JFET region 222 that are not implanted with additional n-type dopants are the portions where the highest electrical field values would otherwise appear (i.e., in a device having a uniformly doped JFET region) during reverse blocking operation, the MOSFET 200 may have reduced peak electrical field values in the gate oxide layers 160 thereof during reverse blocking operation, and hence may exhibit improved reliability with almost no reduction in on-state resistance performance.

The MOSFET 200 of FIGS. 6A-6B can be formed, for example, using a slightly modified version of the method of FIGS. 4A-4F described above. In particular, the energies used during the six (or more) angled ion implantation processes may be increased, and the implantation angles may be increased, so that the n-type dopants are implanted completely underneath portions of the first patterned mask 112 that extend between parallel sidewalls of adjacent p-wells 130. However, due to the angles of these implants, the n-type dopants are (mostly) not implanted into the triangular regions 126, thereby leaving a plurality of un-implanted second JFET sub-regions 224B.

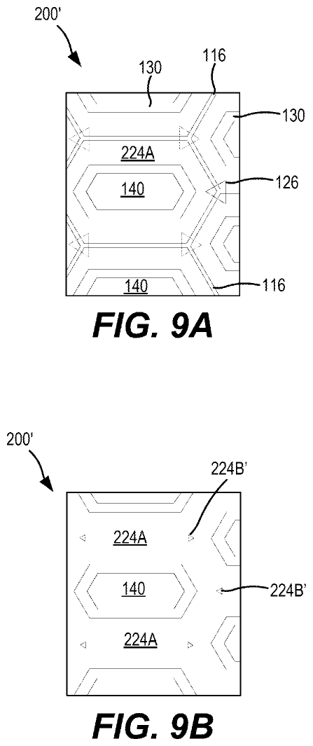

A MOSFET 200′ that is similar to the MOSFET 200 of FIGS. 6A-6B can also be formed using a slightly modified version of the method of FIGS. 5A-5F described above. As shown in FIG. 9A, the process of FIGS. 5A-5F may be performed where a width of the first patterned mask 116 is made very small (e.g., 0.1 or 0.2 microns) in regions of the device that are in between parallel sidewalls of the regions in the semiconductor layer structure 150 where the p-wells 130 will eventually be formed. The patterned mask 116 extends on the upper surface of the semiconductor layer structure 150 with the mask material extending midway between sidewalls of adjacent p-wells 130. A JFET implant is then performed to implant n-type dopants into exposed regions of the semiconductor layer structure 150. A non-channeled (standard) ion implantation process may be used so that increased straggle occurs during the implant. Because of this straggle and the very thin width of the patterned mask 116, n-type dopants are implanted underneath the mask so that the entire JFET region between parallel sidewalls of adjacent p-wells 130 is implanted, although the regions underneath the patterned mask 116 may not be implanted as heavily as the exposed portions of the JFET region 122.

As shown in FIG. 9A, at the centroid of the triangular regions 126 the patterned mask 116 is widened slightly as three thin mask sections merge together. Consequently, the number of dopants implanted into this region may be smaller, and/or a portion of each triangular region 126 may remain un-implanted to form a plurality of small un-implanted regions 224B′, as shown in FIG. 9B. While these under-implanted/un-implanted regions 224B′ may be small, they are formed at the locations where the electric field values would be the highest in the JFET region 122 during reverse blocking operation if the JFET region 122 was uniformly doped. Consequently, the selective implant in this modified method may implant most of the JFET region 122, but since it does not implant the portions where the electric field would be the highest, they can provide a meaningful improvement in reliability, and may do so with little impact in the on-state resistance.

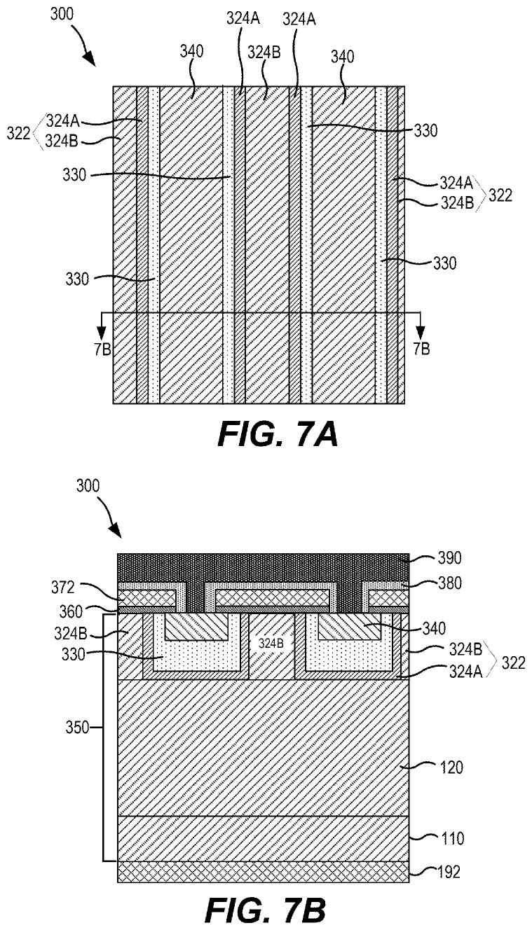

FIG. 7A is a schematic plan view of a top surface of a semiconductor layer structure of a power MOSFET 300 that can be fabricated using certain methods according to embodiments of the present invention. FIG. 7B is a schematic cross-sectional diagram taken along the line 7B-7B of FIG. 7A with portions of the upper metallization and dielectric layers of power MOSFET 300 added for context.

Referring to FIGS. 7A-7B, it can be seen that the MOSFET 300 has the stripe configuration. In particular, the MOSFET 300 includes the same regions and elements as MOSFET 100, but these regions and elements have different shapes in MOSFET 300 due to the stripe configuration. In particular, in MOSFET 300, the JFET regions 322, the p-wells 330, the source regions 340, the gate oxide layers 360, the gate electrodes 372 and the intermetal dielectric layers 380 may all appear as stripes having generally uniform widths that extend longitudinally across an active region of the MOSFET 300. The first and second JFET sub-regions 324A, 324B may also be formed as longitudinally-extending stripes that extend between the p-wells 330.

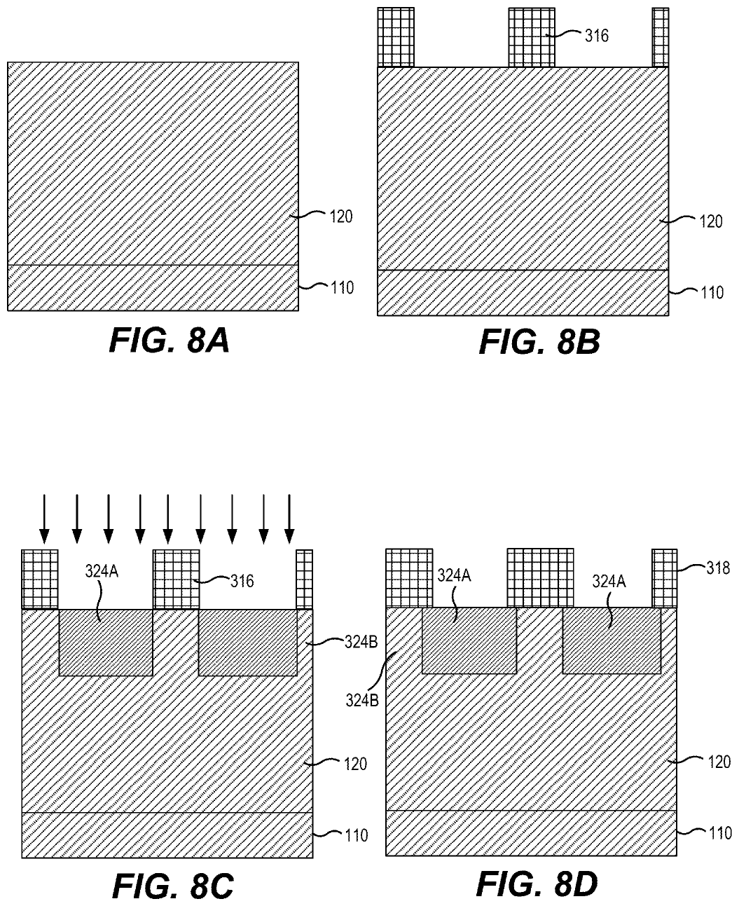

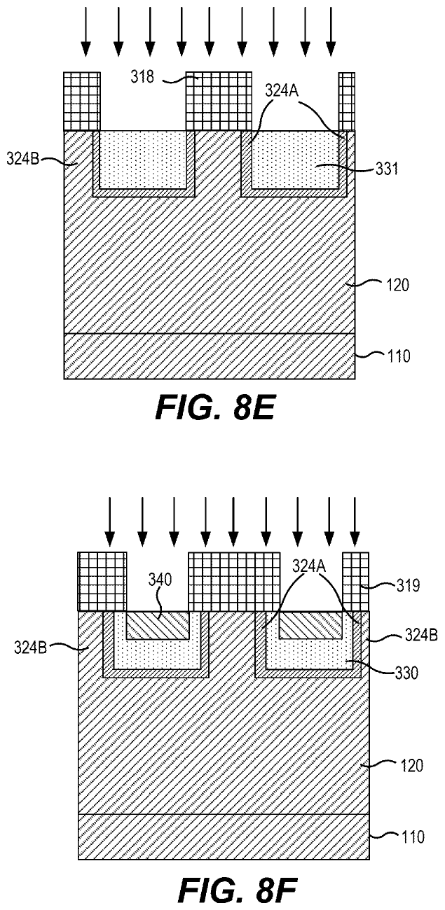

FIGS. 8A-8F are schematic cross-sectional diagrams illustrating a method according to embodiments of the present invention of fabricating the power MOSFET of FIGS. 7A-7B.

Referring to FIG. 8A, an n-type silicon carbide drift layer 120 is epitaxially grown on the heavily-doped n-type silicon carbide substrate 110. The drift layer 120 may be doped n-type during the epitaxial growth process. The substrate 110 and the drift layer 120 may be identical to the correspondingly numbered elements of MOSFET 100.

Referring to FIG. 8B, an ion implantation mask layer (e.g., a silicon oxide mask) is formed on the upper surface of the drift layer 120 and then patterned to form a first patterned mask 316 that exposes regions where the first JFET sub-regions 324A, the p-wells 330 and the source regions 340 will be formed. Referring to FIG. 7A, the first patterned mask 316 may exactly cover the region that will become the second JFET sub-region 324B of the MOSFET 300.

Referring to FIG. 8C, next, a vertical (i.e., non-angled) ion implantation process is performed using the first patterned mask 316 to selectively implant n-type dopants into the upper surface of the drift layer 120. This ion implantation step is used to implant the portions of the semiconductor layer structure 350 that will ultimately form the first JFET sub-regions 324A, the p-wells 330 and the source regions 340. The portions of the semiconductor layer structure 350 that will ultimately become the second JFET sub-region 324B is shielded by the first patterned mask 316 and hence is not implanted with additional n-type dopants.

Referring to FIG. 8D, next, a first spacer process is used to widen the first patterned mask 316 to convert it into a second patterned mask 318. The first spacer process may, for example, be the same spacer process described above with reference to FIG. 4E. The widened portion of the second patterned mask 318 covers the portions of the semiconductor layer structure 350 that will ultimately form the first JFET sub-regions 324A.

Referring to FIG. 8E, next, a standard ion implantation process is performed to implant p-type dopants into the exposed surfaces of the semiconductor layer structure 350 in order to form preliminary p-wells 331.

Referring to FIG. 8F, next, a second spacer process is used to widen the second patterned mask 318 to convert it into a third patterned mask 319. The second spacer process may, for example, be the same spacer process described above with reference to FIG. 4E. The widened portion of the third patterned mask 319 may cover the entirety of the semiconductor layer structure 350 in the active region of the MOSFET 300 except for the portions of the device that will ultimately be the source regions 340. Then, a standard ion implantation process is performed to implant n-type dopants into the exposed surfaces of the semiconductor layer structure 350 in order to form the source regions 340, which also has the effect of converting the preliminary p-wells 331 into the p-wells 330. The third patterned mask 319 is then removed.

Referring to FIG. 7B, the gate dielectric layer 360, gate electrode 370, intermetal dielectric layer 380 and source metallization layer 390 are formed on the upper surface of the semiconductor layer structure 350, and the drain contact 192 is formed on the lower surface of the semiconductor layer structure 350. These layers may be formed in conventional fashion and hence description of the fabricating steps used to form these layers will be omitted here.

In the above description, MOSFETs having a cell configuration have been described with respect to MOSFETs that have hexagonally-shaped cells (e.g., hexagonally-shaped p-wells with hexagonally-shaped source regions therein). It will be appreciated, however, that embodiments of the present invention are not limited thereto, and that the principles of the present disclosure apply equally to MOSFETs having cell configurations with p-wells having other shapes including, for example, MOSFETs having triangular, rectangular (e.g., square), and octagonal shaped p-wells.

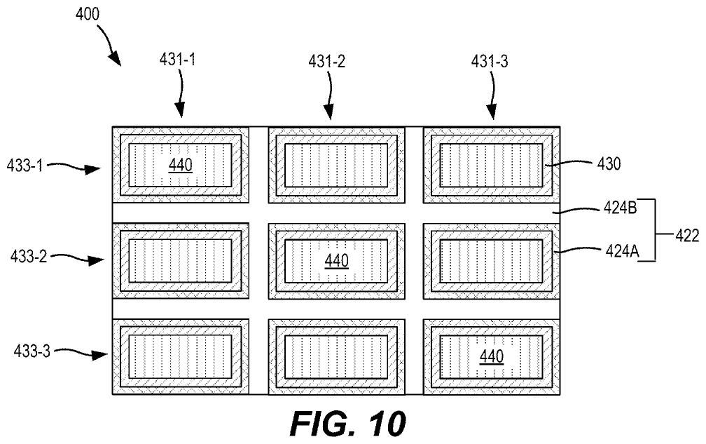

FIG. 10 is a schematic plan view of a top surface of the semiconductor layer structure of a cell configuration power MOSFET 400 according to embodiments of the present invention that includes cells that have rectangular shapes as opposed to hexagonal cells. In FIG. 10, the upper polysilicon, metal and dielectric layers are omitted so that the upper surface of the silicon carbide semiconductor layer structure of the MOSFET 400 is visible. The power MOSFET 400 is similar to power MOSFET 100 of FIGS. 3A-3C, with the one difference being that power MOSFET 400 has a rectangular cell configuration instead of a hexagonal cell configuration.

As shown in FIG. 10, the MOSFET 100 has a plurality of cells that are arranged in columns (columns 431-1 through 431-3 are visible in FIG. 10) and rows (rows 433-1 through 433-3 are visible in FIG. 10). Each cell of MOSFET 400 includes a p-type well 430 that has an n-type source region formed therein. A JFET region 422 is formed in/on the upper portion of a drift region (not visible in FIG. 10). The cells 430/440 are formed as islands in the JFET region 422, as is shown in the plan view of FIG. 10. The JFET region 422 includes a plurality of first JFET sub-regions 424A and a continuous second JFET sub-region 424B that extends around and surrounds each of the first JFET sub-regions 424A. The first JFET sub-regions 424A may be implanted regions while the second sub-region 424B may be an un-implanted region.

The above-described methods according to embodiments of the present invention may have certain advantages over conventional MOSFET fabrication techniques. For example, these techniques allow the JFET implant to be aligned with the p-wells without requiring a separate lithography and patterning step. This reduces the required number of mask levels by at least one, and eliminates the need for several fabrication steps, which reduces cost and improves throughput. In addition, since the JFET implant is aligned with the p-wells, misalignment between the JFET implant and the p-wells is avoided which improves the performance-reliability tradeoff. Moreover, some of the fabrication methods use multiple spacer processes avoid the need for angled ion implantation steps, which can simplify fabrication. Since angled ion implantation processes are not used in these techniques, channeled ion implants may be used to form the p-wells and/or the JFET implants. Such channeled ion implants may exhibit reduced straggle and provide better-shaped regions, which may enhance device performance.

While the above discussion focuses on n-channel MOSFETs, it will be appreciated that pursuant to further embodiments of the present invention, the polarity of each of the semiconductor layers in each device could be reversed so as to provide corresponding p-channel MOSFETs. Likewise, while the embodiments of the present invention discussed above are MOSFETs, it will be appreciated that the techniques disclosed herein may also be used to form insulated gate bipolar junction transistors (IGBTs) that include a MOSFET according to embodiments of the present invention, or other gate controlled power semiconductor devices.

Herein, embodiments of the present invention are described with respect to cross-sectional diagrams that show one or two unit cells of a power switching devices. It will be appreciated that actual implementations will typically include a much larger number of unit cells. However, it will also be appreciated that the present invention is not limited to such devices, and that the claims appended hereto also cover MOSFETs and other power switching devices that comprise, for example, a single unit cell. Moreover, while the present disclosure focuses on silicon carbide devices, it will be appreciated that embodiments of the present invention may also have applicability to devices formed using other wide band-gap semiconductors such as, for example, gallium nitride, zinc selenide or any other II-VI or III-V wide band-gap compound semiconductors.

The invention has been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the invention are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device, comprising:
a semiconductor layer structure that includes a drift layer having a first conductivity type;
a JFET region that has the first conductivity type in the upper portion of the drift layer;
a plurality of well regions having a second conductivity type in an upper portion of the drift layer, each well region forming a respective island within the JFET region when viewed in plan view; and
a plurality of source regions having the first conductivity type, where each source region is within a respective one of the well regions,
wherein the JFET region comprises a plurality of spaced-apart first JFET sub-regions that each has a first doping concentration and a second JFET sub-region that has a second doping concentration that is lower than the first doping concentration, the second JFET region extending around at least one of the first JFET sub-regions when viewed in plan view.

2. The semiconductor device of claim 1, wherein the first JFET sub-regions comprise implanted regions and the second JFET sub-region comprises an un-implanted region.

3. The semiconductor device of claim 1, wherein the plurality of well regions are arranged in columns, where the well regions in adjacent columns are offset from each other in a column direction.

4. The semiconductor device of claim 3, wherein each well region has a hexagonal shape when viewed in plan view.

5. The semiconductor device of claim 4, wherein each first JFET sub-region has an annular hexagonal shape when viewed in plan view.

6. The semiconductor device of claim 4, wherein each first JFET sub-region surrounds a respective one of the well regions when viewed in plan view.

7. The semiconductor device of claim 4, wherein each first JFET sub-region is positioned between a respective one of the well regions and the second JFET sub-region when the semiconductor device is viewed in plan view.

8. The semiconductor device of claim 1, wherein the second JFET sub-region comprises a continuous region that surrounds each of the first JFET sub-regions.

9. The semiconductor device of claim 1, wherein the plurality of well regions are arranged in columns, where the well regions in adjacent columns are offset from each other in a column direction.

10. A semiconductor device, comprising:
a semiconductor layer structure that includes a drift layer having a first conductivity type;
a JFET region that has the first conductivity type in the upper portion of the drift layer;
a plurality of well regions having a second conductivity type in an upper portion of the drift layer, each well region forming a respective island within the JFET region; and
a plurality of source regions having the first conductivity type, where each source region is within a respective one of the well regions,
wherein the FET region comprises a plurality of spaced-apart first JFET sub-regions that each has a first doping concentration and a second JFET sub-region that has a second doping concentration that is lower than the first doping concentration, the second JFET region extending around at least one of the well regions.

11. The semiconductor device of claim 10, wherein the first JFET sub-regions comprise implanted regions and the second JFET sub-region comprises an un-implanted region.

12. The semiconductor device of claim 10, wherein the plurality of well regions are arranged in columns.

13. The semiconductor device of claim 12, wherein the well regions in adjacent columns are offset from each other in a column direction.

14. The semiconductor device of claim 13, wherein each first JFET sub-region has an annular hexagonal shape when viewed in plan view.

15. The semiconductor device of claim 14, wherein each first JFET sub-region surrounds a respective one of the well regions when viewed in plan view.

16. The semiconductor device of claim 12, wherein each first JFET sub-region has an annular rectangular shape when viewed in plan view.

17. The semiconductor device of claim 10, wherein the second JFET sub-region comprises a continuous region that surrounds each of the first JFET sub-regions.

18. A semiconductor device, comprising:
a semiconductor layer structure that includes a drift layer having a first conductivity type;
a JFET region that has the first conductivity type in the upper portion of the drift layer;
a plurality of well regions having a second conductivity type in an upper portion of the drift layer, each well region forming a respective island within the JFET region; and
a plurality of source regions having the first conductivity type, where each source region is within a respective one of the well regions,
wherein the FET region comprises a continuous first JFET sub-region that extends around the plurality of well regions and that has a first doping concentration and a plurality of spaced-apart second JFET sub-regions that each has a second doping concentration, where the second doping concentration is lower than the first doping concentration.

19. The semiconductor device of claim 18, wherein the first JFET sub-region comprises an implanted region and the second JFET sub-regions comprise un-implanted regions.

20. The semiconductor device of claim 18, wherein each well region has a hexagonal shape when viewed in plan view.

21. The semiconductor device of claim 20, wherein each second FET sub-region has a triangular shape when viewed in plan view.

22-56. (canceled)
